(19) United States
(12) Patent Application Publication
(10) Pub. No.: US 2022/0066199 A1
(43) Pub. Date: Mar. 3, 2022

(54) MICRO SCANNING MIRROR

(71) Applicant: Coretronic MEMS Corporation, MIAOLI COUNTY (TW)

(72) Inventors: Hsi-Wen Tung, MIAOLI COUNTY (TW); Ming-Ching Wu, MIAOLI COUNTY (TW)

(73) Assignee: Coretronic MEMS Corporation, MIAOLI COUNTY (TW)

(21) Appl. No.: 17/411,063

(22) Filed: Aug. 25, 2021

(30) Foreign Application Priority Data
Aug. 27, 2020 (CN) 202010876578.9

(51) Int. Cl. G02B 26/08; G02B 26/10; H02N 2/10

(52) U.S. Cl. CPC G02B 26/0858; H02N 2/108; G02B 26/101

(57) ABSTRACT

A micro scanning mirror includes a lens, a piezoelectric material layer, two first rotating shaft elements, and first driving electrodes. A first axial direction passes through a center of the lens. The piezoelectric material layer is arranged along a circumferential direction of the lens and has first driving electrode regions. Each first spacing region where the piezoelectric material layer is not disposed is formed between two adjacent first driving electrode regions. Each first rotating shaft element is located between one of the first spacing regions and the corresponding adjacent first driving electrode region, and the first rotating shaft element connect the lens and the piezoelectric material layer located in the first driving electrode regions. The first driving electrodes are respectively located on the corresponding first driving electrode regions. The micro scanning mirror can obtain a large rotation angle of the mirror on the same driving condition and has good reliability.

### CROSS-REFERENCE TO RELATED APPLICATION

This application claims the priority benefit of China application serial no. 202010876578.9, filed on Aug. 27, 2020. The entirety of the above-mentioned patent application is hereby incorporated by reference herein and made a part of this specification.

### BACKGROUND OF THE INVENTION

### 1. Field of the Invention

The invention relates to a micro-electro-mechanical system (MEMS) device and particularly relates to a micro scanning mirror.

### 2. Description of Related Art

Micro scanning mirrors made by micro-electro-mechanical technology may be divided into three categories according to the driving manner thereof: electrostatic actuation, electromagnetic actuation, and piezoelectric actuation.

The micro-mirror adopting the electrostatic actuation technology is currently the mainstream product in the market but is subject to high voltage operation and sensitivity to collision or vibration. More specifically, two high-voltage electrodes of the micro-mirror adopting the electrostatic actuation technology are usually spaced from each other by only a few micrometers. Once the structure is slightly displaced due to collision or vibration resulting from an external force, the two electrodes may be adhered to each other or may be in contact and encounter the short circuit issue, whereby the entire system may be malfunctioned.

On the other hand, in the micro-mirror adopting the electromagnetic actuation technology, the rotation angle of the mirror is controlled by the operation current, and such a micro-mirror is also subject to high power consumption and the influence of heat generated on the overall structure by the current. In addition, the micro-mirror adopting the electromagnetic actuation technology also relies on an external magnet to provide a magnetic field, which not only complicates the assembly process but also limits the possibility of reducing its packaging size. In addition, the existing micro-mirror adopting the electromagnetic actuation technology may only be driven in a one-shaft manner and thus may merely perform the scanning operation in one dimension but not in two dimensions.

The existing micro-mirror adopting the piezoelectric actuation technology has two driving modes. One is to apply a gimble structure to connect the micro-mirror to a ring frame through a first rotation shaft (e.g., the X axis), and a second rotation shaft (e.g., the Y axis) is arranged on the ring frame in a direction perpendicular to the first rotation shaft and connects the ring frame and a fixing end of a chip substrate. The other is to directly place four sets of driving portions on the fixing end of the chip substrate without using the ring frame, two sets of the driving portions are connected to the first rotation shaft of the micro mirror, and the other two sets are connected to the second rotation shaft of the micro mirror. Such a driving mode allows the micro-mirror to be driven in a two-shaft manner, and the rotation shafts are directly driven by different driving portions, so that the micro-mirror rotates around the first rotation shaft or the second rotation shaft. On the other hand, the driving mode adopting the ring frame is designed as a one-shaft driving mode; however, the ring frame may be twisted and deformed through the arrangement of driving electrodes on the ring frame, so as to drive the mirror to rotate around the first rotation shaft or the second rotation shaft.

However, in the existing micro-mirrors adopting the piezoelectric actuation technology, it is necessary to sacrifice a partial region connecting the driving portion and the rotation shafts to arrange sensing electrodes, thus resulting in the failure to maximize the rotation angle of the mirror or optimize the driving manner. Moreover, when the micro-mirror adopting the piezoelectric actuation technology has one single rotation shaft, the resistance to external vibration is relatively unfavorable even though the torsional rigidity remains unchanged.

The information disclosed in this Background section is only for enhancement of understanding of the background of the described technology and therefore it may contain information that does not form the prior art that is already known to a person of ordinary skill in the art. Further, the information disclosed in the Background section does not mean that one or more problems to be resolved by one or more embodiments of the invention was acknowledged by a person of ordinary skill in the art.

### SUMMARY OF THE INVENTION

The invention provides a micro scanning mirror, which can achieve a relatively large rotation angle on the same driving condition and has good reliability.

An embodiment of the invention provides a micro scanning mirror. The micro scanning mirror includes a lens, a piezoelectric material layer, two first rotating shaft elements, and a plurality of first driving electrodes. A first axial direction passes through a center of the lens. The piezoelectric material layer is arranged along a circumferential direction of the lens and has a plurality of first driving electrode regions, and two first spacing regions where the piezoelectric material layer is not disposed are respectively formed between two adjacent first driving electrode regions of the first driving electrode regions. The two first rotating shaft elements are respectively located on two opposite sides of the lens along the first axial direction, and each of the first rotating shaft elements is located between one of the first spacing regions and the corresponding two adjacent first driving electrode regions. Each of the two first rotating shaft elements connects the lens and the piezoelectric material layer located in the corresponding two adjacent first driving electrode regions. The first driving electrodes are respectively located on the corresponding first driving electrode regions. Here, the piezoelectric material layer is driven by the corresponding first driving electrodes, respectively, so that the two first rotating shaft elements drive the lens to rotate around the first axial direction after the piezoelectric material layer located on both sides of each of the first spacing regions is deformed.

Based on the above, one or more embodiments of the invention have at least one of the following advantages or effects. In one or more embodiments of the invention, the micro scanning mirror is provided with the first spacing regions and the second spacing regions where the piezoelectric material layer is not disposed, so that the lens may achieve a relatively large rotation angle when the lens rotates around the first axial direction or the second axial direction, so as to reduce the required driving voltage on the condition of the same rotation angle and to mitigate the difficulty of the driving circuit design. Additionally, in the micro scanning mirror, the fixing end of the substrate and the piezoelectric material layer in the two second driving electrode regions are connected by the second rotating shaft elements, so as to improve the rigidity of the micro scanning mirror and further enhance the reliability of the micro scanning mirror.

Other objectives, features and advantages of the invention will be further understood from the further technological features disclosed by the embodiments of the invention wherein there are shown and described preferred embodiments of this invention, simply by way of illustration of modes best suited to carry out the invention.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. The accompanying drawings are included to provide a further understanding of the invention, and are incorporated in and constitute a part of this specification. The drawings illustrate embodiments of the invention and, together with the description, serve to explain the principles of the invention.

FIG. 1A is a schematic front view of a micro scanning mirror according to an embodiment of the invention.

FIG. 1B is a schematic cross-sectional view of the micro scanning mirror in FIG. 1A along a line A-A or a line B-B.

FIG. 1C is a schematic front view of the first rotating shaft elements in FIG. 1A.

FIG. 1D is a schematic front view of the second rotating shaft elements in FIG. 1A.

FIG. 2A to FIG. 2C are schematic views illustrating that the micro scanning mirror in FIG. 1A rotates around a first axial direction.

FIG. 3A to FIG. 3C are schematic views illustrating that the micro scanning mirror in FIG. 1A rotates around a second axial direction.

FIG. 4 is a schematic front view of a micro scanning mirror according to a comparative example of the invention.

FIG. 5A to FIG. 5C are schematic front views of different first rotating shaft elements according to another embodiment of the invention.

FIG. 6 is a schematic front view of second rotating shaft elements according to another embodiment of the invention.

### DESCRIPTION OF THE EMBODIMENTS

In the following detailed description of the preferred embodiments, reference is made to the accompanying drawings which form a part hereof, and in which are shown by way of illustration specific embodiments in which the invention may be practiced. In this regard, directional terminology, such as “top,” “bottom,” “front,” “back,” etc., is used with reference to the orientation of the Figure(s) being described. The components of the invention can be positioned in a number of different orientations. As such, the directional terminology is used for purposes of illustration and is in no way limiting. On the other hand, the drawings are only schematic and the sizes of components may be exaggerated for clarity. It is to be understood that other embodiments may be utilized and structural changes may be made without departing from the scope of the invention. Also, it is to be understood that the phraseology and terminology used herein are for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” “coupled,” and “mounted” and variations thereof herein are used broadly and encompass direct and indirect connections, couplings, and mountings. Similarly, the terms “facing,” “faces” and variations thereof herein are used broadly and encompass direct and indirect facing, and “adjacent to” and variations thereof herein are used broadly and encompass directly and indirectly “adjacent to”. Therefore, the description of “A” component facing “B” component herein may contain the situations that “A” component directly faces “B” component or one or more additional components are between “A” component and “B” component. Also, the description of “A” component “adjacent to” “B” component herein may contain the situations that “A” component is directly “adjacent to” “B” component or one or more additional components are between “A” component and “B” component. Accordingly, the drawings and descriptions will be regarded as illustrative in nature and not as restrictive.

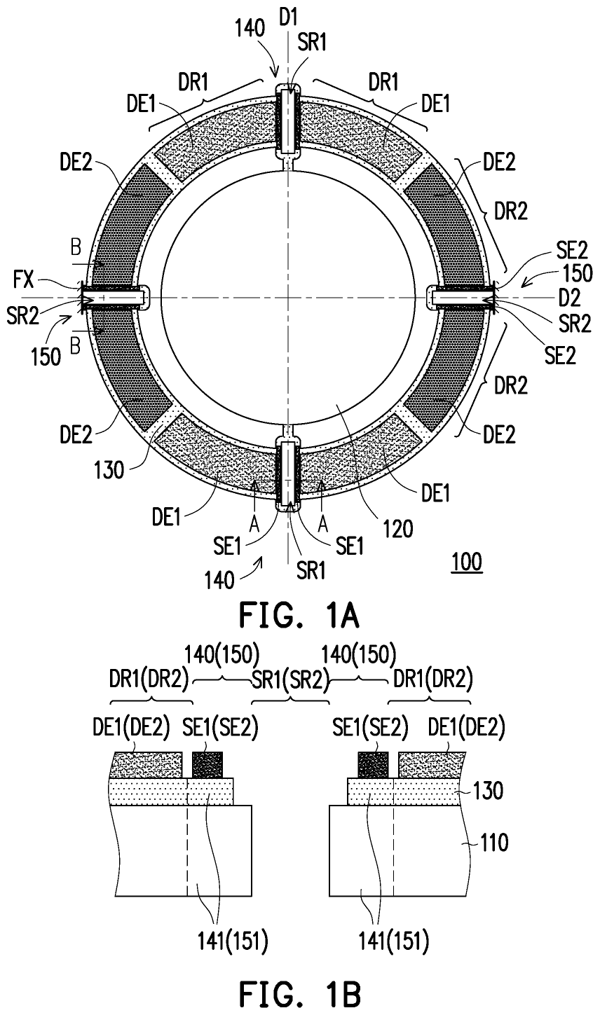

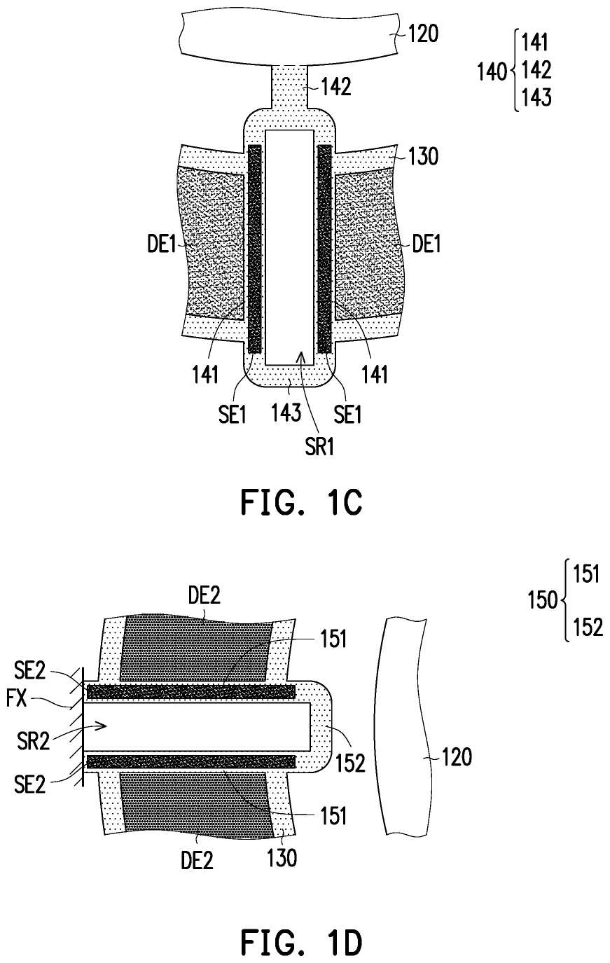

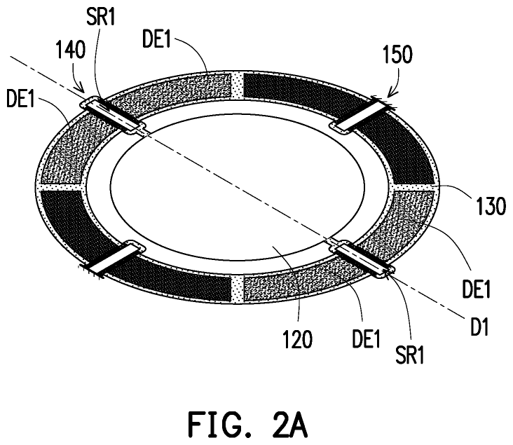

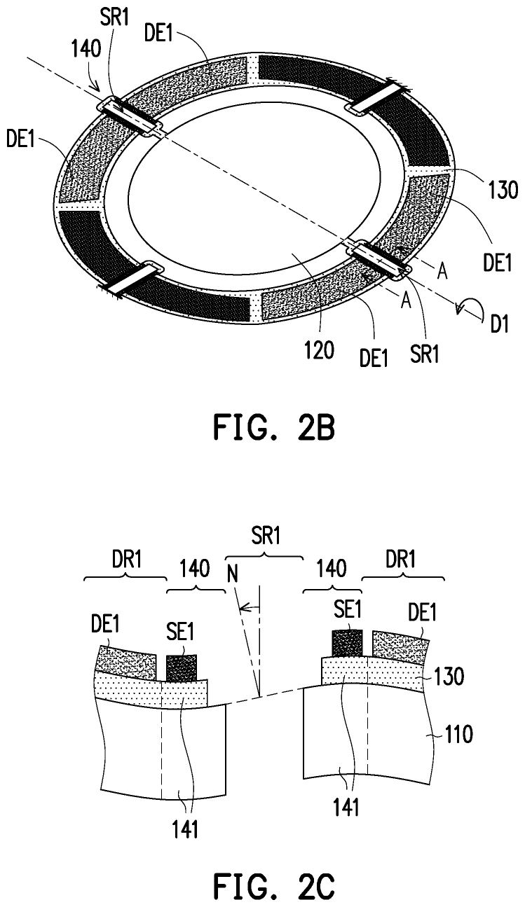

FIG. 1A is a schematic front view of a micro scanning mirror according to an embodiment of the invention. FIG. 1B is a schematic cross-sectional view of the micro scanning mirror in FIG. 1A along a line A-A or a line B-B. FIG. 1C is a schematic front view of the first rotating shaft elements in FIG. 1A. FIG. 1D is a schematic front view of the second rotating shaft elements in FIG. 1A. Please refer to FIG. 1A and FIG. 1B. The micro scanning mirror 100 provided in this embodiment includes a substrate 110, a lens 120, a piezoelectric material layer 130, two first rotating shaft elements 140, two second rotating shaft elements 150, a plurality of first driving electrodes DE1, and a plurality of second driving electrodes DE2. For instance, in this embodiment, a material of the substrate 110 is silicon, which should however not be construed as a limitation to the invention. Besides, as shown in FIG. 1A and FIG. 1B, in this embodiment, note that the schematic cross-sectional view of the micro scanning mirror 100 along the line A-A shows a cross-sectional structure of the piezoelectric material layer 130, the first rotating shaft elements 140, and the first driving electrodes DE1 which are relatively stacked, and the schematic cross-sectional view of the micro scanning mirror 100 along the line B-B shows a cross-sectional structure of the piezoelectric material layer 130, the second rotating shaft elements 150, and the second driving electrodes DE2 which are relatively stacked.

Specifically, as shown in FIG. 1A and FIG. 1B, in this embodiment, the piezoelectric material layer 130, the first driving electrodes DE1, and the second driving electrodes DE2 may be disposed on the substrate 110. As shown in FIG. 1A, in this embodiment, a first axial direction D1 and a second axial direction D2 both pass through a center of the lens 120, and the first axial direction D1 and the second axial direction D2 are parallel to the mirror surface. To be specific, as shown in FIG. 1A, the first axial direction D1 and the second axial direction D2 are orthogonal to each other, and the first axial direction D1 and the second axial direction D2 intersect at the center of the lens 120.

Furthermore, as shown in FIG. 1A, in this embodiment, the piezoelectric material layer 130 is arranged along a circumferential direction of the lens 120. As shown in FIG. 1A and FIG. 1B, in this embodiment, the piezoelectric material layer 130 has a plurality of first driving electrode regions DR1 and a plurality of second driving electrode regions DR2, the first driving electrodes DE1 are respectively located on the corresponding first driving electrode regions DR1, and the second driving electrodes DE2 are respectively located on the corresponding second driving electrode regions DR2. Additionally, as shown in FIG. 1A and FIG. 1B, in this embodiment, two first spacing regions SR1 where the piezoelectric material layer 130 is not disposed are respectively formed between the two adjacent first driving electrode regions DR1. Similarly, two second spacing regions SR2 where the piezoelectric material layer 130 is not disposed are respectively formed between the two adjacent second driving electrode regions DR2. Further, as shown in FIG. 1A, in this embodiment, the first axial direction D1 passes through the two first spacing regions SR1, and the second axial direction D2 passes through the two second spacing regions SR2.

On the other hand, as shown in FIG. 1A and FIG. 1C, in this embodiment, the two first rotating shaft elements 140 are respectively located on two opposite sides of the lens 120 along the first axial direction D1, and each of the two first rotating shaft elements 140 is located between one of the two first spacing regions SR1 and the corresponding two adjacent first driving electrode regions DR1. Each of the two first rotating shaft elements 140 connects the lens 120 and the piezoelectric material layer 130 located in the corresponding two adjacent first driving electrode regions DR1.

More specifically, as shown in FIG. 1C, in this embodiment, each of the two first rotating shaft elements 140 has two first extension portions 141, a first inner connection portion 142, and an outer connection portion 143. The first inner connection portion 142 is connected to the lens 120, and the first axial direction D1 passes through the first inner connection portion 142. As shown in FIG. 1C, in this embodiment, the first inner connection portion 142 extends from both ends of the lens 120 toward a radially-outer side of the lens 120 and then branches off to form the two first extension portions 141. The first inner connection portion 142 of each first rotating shaft element 140 is closer to the lens 120 than an inner circumference of the piezoelectric material layer 130 located on both sides of each first spacing region SR1. Besides, as shown in FIG. 1C, in this embodiment, the outer connection portion 143 protrudes from one end of the two first extension portions 141 and extends along a circumferentially-outer side of the piezoelectric material layer 130, so that the two first extension portions 141 are connected to each other. The outer connection portion 143 of each first rotating shaft element 140 is farther away from the lens 120 than an outer circumference of the piezoelectric material layer 130 located on both sides of each first spacing region SR1. The outer connection portion 143, the first inner connection portion 142, and the two first extension portions 141 form a boundary that surrounds the first spacing regions SR1, so that the first rotating shaft elements 140 have a close-end outline shaped as a letter O.

On the other hand, as shown in FIG. 1A and FIG. 1D, in this embodiment, the two second rotating shaft elements 150 are respectively located on two opposite sides of the lens 120 along the second axial direction D2, and each of the two second rotating shaft elements 150 is located between one of the two second spacing regions SR2 and the corresponding two adjacent second driving electrode regions DR2. Each second rotating shaft element 150 is connected to a fixing end FX of the substrate 110 and located at the piezoelectric material layer 130 in the two second driving electrode regions DR2.

More specifically, as shown in FIG. 1D, in this embodiment, each second rotating shaft element 150 has two second extension portions 151 and a second inner connection portion 152. The second inner connection portion 152 extends from the piezoelectric material layer 130 located on both sides of each of the two second spacing regions SR2 along a circumferentially-inner side of the piezoelectric material layer 130, so that the piezoelectric material layer located on both sides of each of the second spacing regions SR2 are connected to each other. Each of the second inner connection portions 152 extends from a radially-inner side of the piezoelectric material layer 130 toward a radially-outer side of the piezoelectric material layer 130 to form the two second extension portions 151, and the two second extension portions 151 are connected to the piezoelectric material layer 130 in the two adjacent second driving electrode regions DR2. The second inner connection portion 152 of each of the second rotating shaft elements 150 is closer to the lens 120 than an inner circumference of the piezoelectric material layer 130 located on both sides of each of the two second spacing regions SR2.

Moreover, as shown in FIG. 1A to FIG. 1D, in this embodiment, the micro scanning mirror 100 further includes a plurality of first sensing electrodes SE1 and a plurality of second sensing electrodes SE2. The first sensing electrodes SE1 are located on the two first extension portions 141 of the first rotating shaft elements 140, and the second sensing electrodes SE2 are located on the two second extension portions 151 of the two second rotating shaft elements 150. For instance, in this embodiment, a material of the first rotating shaft elements 140 and the second rotating shaft elements 150 may include silicon and piezoelectric materials; in other words, the first rotating shaft elements 140 and the second rotating shaft elements 150 may include the substrate 110 and the piezoelectric material layer 130 extending to a portion between the first spacing regions SR1 and the corresponding two adjacent first driving electrode regions DR1. Specifically, the piezoelectric materials included in the first rotating shaft elements 140 are required to be placed below the first sensing electrodes SE1 and connected to the piezoelectric material layer 130 in the two first driving electrode regions DR1, so that the piezoelectric materials and the piezoelectric material layer 130 are formed integrally and may serve to sense changes to electric charges when the piezoelectric material layer 130 is driven by the first driving electrodes DE1 and may then serve to reversely infer displacement changes or angle changes of the lens 120 of the micro scanning mirror 100 rotating around the first axial direction D1. Similarly, the piezoelectric materials included in the second rotating shaft elements 150 are also required to be placed below the second sensing electrodes SE2 and connected to the piezoelectric material layer 130 in the two second driving electrode regions DR2, so that the piezoelectric materials and the piezoelectric material layer 130 are formed integrally and may serve to sense changes to electric charges when the piezoelectric material layer 130 is driven by the second driving electrodes DE2 and may then serve to reversely infer displacement changes or angle changes of the lens 120 of the micro scanning mirror 100 rotating around the second axial direction D2.

In other words, as shown in FIG. 1B to FIG. 1D, in this embodiment, the two first extension portions 141 of each first rotating shaft element 140 and the two second extension portions 151 of each second rotating shaft element 150 may be formed by a laminated layer including a silicon-containing substrate and the piezoelectric materials. As shown in FIG. 1C and FIG. 1D, in this embodiment, a material of the other portions of the first rotating shaft elements 140 (such as the first inner connection portion 142 and the outer connection portion 143) and a material of the other portions of the second rotating shaft elements (such as the second inner connection portion 152) may only be silicon-containing base materials, and the silicon-containing portions of the first rotating shaft elements 140 and the second rotating shaft elements 150 and the substrate 110 are integrally formed, so that the first rotating shaft elements 140 and the second rotating shaft elements 150 may drive the lens 120 to rotate based on the deformation of the piezoelectric material layer 130 and the substrate 110.

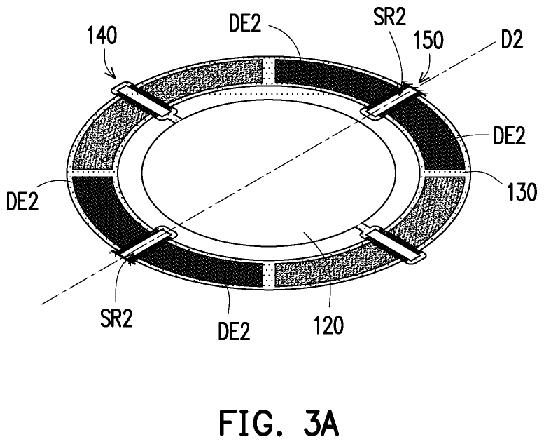

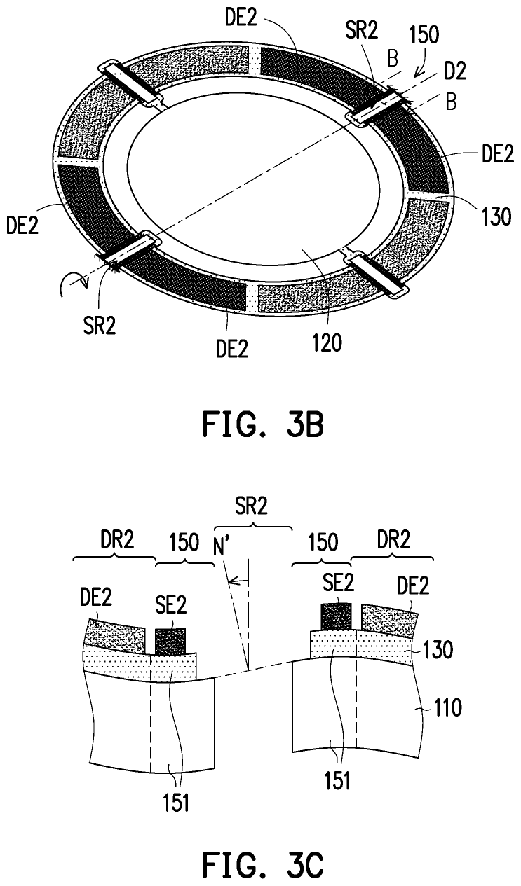

The process of the micro scanning mirror 100 rotating around the first axial direction D1 or rotating around the second axial direction D2 will be further explained below with reference to FIG. 2A to FIG. 3C.

FIG. 2A to FIG. 2C are schematic views illustrating that the micro scanning mirror in FIG. 1A rotates around a first axial direction. FIG. 3A to FIG. 3C are schematic views illustrating that the micro scanning mirror in FIG. 1A rotates around a second axial direction. As shown in FIG. 2A to FIG. 2C, in this embodiment, when it is intended to drive the micro scanning mirror 100 to rotate around the first axial direction D1, different voltages may be applied to the first driving electrodes DE1 located on two sides of each first spacing region SR1, and a direction of a driving voltage applied to the piezoelectric material layer 130 by the first driving electrodes DE1 close to one side of each of the first spacing regions SR1 is opposite to a direction of a driving voltage applied to the piezoelectric material layer 130 by the first driving electrodes DE1 close to the other side of each of the first spacing regions SR1.

Accordingly, as shown in FIG. 2B and FIG. 2C, since the piezoelectric material layer 130 is driven by the corresponding first driving electrodes DE1, respectively, the piezoelectric material layer 130 located on both sides of each of the first spacing regions SR1 is deformed. To be specific, when an electric field is applied to upper and lower ends of the piezoelectric material layer 130, the size of the piezoelectric material layer 130 in a direction perpendicular to the electric field (i.e., the horizontal direction) is reduced, but the size of the substrate 110 bonded to the piezoelectric material layer 130 is not changed together with the applied electric field. Therefore, such mismatch in size leads to the fact that the overall structure of the piezoelectric material layer 130 and the substrate 110 bends toward the direction perpendicular to the electric field, so that the size of the bonding surface remains consistent. In other words, the deformation of the piezoelectric material layer 130 drives the substrate 110 to bend in a certain direction and accordingly deform.

In addition, since the directions of the driving voltages applied to the first driving electrodes DE1 on two sides of the first spacing regions SR1 are opposite, as shown in FIG. 2C, the piezoelectric material layer 130 located on both sides of each of the first spacing regions SR1 130 also drives the substrate 110 to deform in opposite directions. When one side is bent in one direction, the other side is deformed in an opposite direction. Thereby, as shown in FIG. 2B and FIG. 2C, the deformation of the substrate 110 and the piezoelectric material layer 130 located on both sides of each of the first spacing regions SR1 results in changes to a normal direction N of the first rotating shaft elements 140; moreover, the first rotating shaft elements 140 drive the lens 120 to rotate around the first axial direction D1.

On the other hand, similarly, as shown in FIG. 3A to FIG. 3C, in this embodiment, when it is intended to drive the micro scanning mirror 100 to rotate around the second axial direction D2, different voltages may be applied to the second driving electrodes DE2 located on two sides of each second spacing region SR2, and a direction of a driving voltage applied to the piezoelectric material layer 130 by the second driving electrodes DE2 close to one side of each of the second spacing regions SR2 is opposite to a direction of a driving voltage applied to the piezoelectric material layer 130 by the second driving electrodes DE2 close to the other side of each of the second spacing regions SR2. Accordingly, as shown in FIG. 3B and FIG. 3C, since the piezoelectric material layer 130 is driven by the corresponding second driving electrodes DE2, respectively, the piezoelectric material layer 130 located on both sides of each of the second spacing regions SR2 is deformed. The mechanism of deformation of the piezoelectric material layer 130 located on both sides of each second spacing region SR2 is the same as that of the piezoelectric material layer 130 located on both sides of each first spacing region SR1 and thus will not be further explained hereinafter. Thereby, as shown in FIG. 3C, the deformation of the substrate 110 and the piezoelectric material layer 130 located on both sides of each of the second spacing regions SR2 results in changes to a normal direction N′ of the second rotating shaft elements 150. Incidentally, as shown in FIG. 3B and FIG. 3C, the integrally formed portion of the second rotating shaft elements 150 and the substrate 110 also drives the other portions of the substrate 110 and the piezoelectric material layer 130 to deform, so that the second rotating shaft elements 150 drive the lens 120 to rotate around the second axial direction D2.

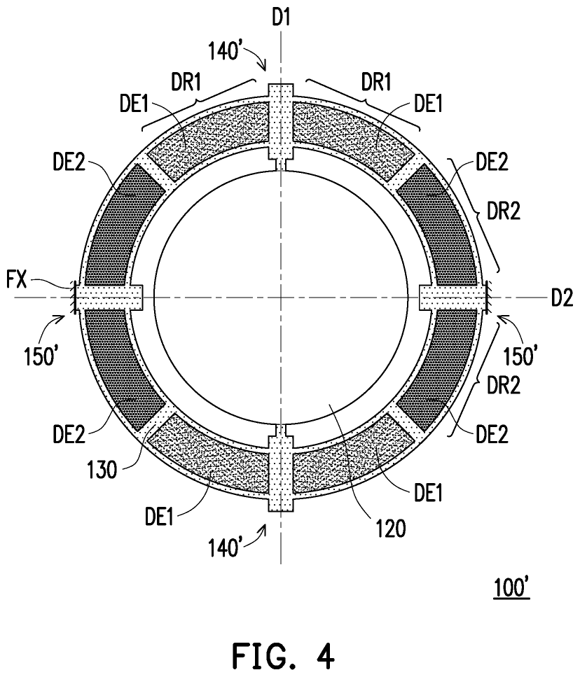

FIG. 4 is a schematic front view of a micro scanning mirror according to a comparative example of the invention. With reference to FIG. 4, the micro scanning mirror 100′ provided in the comparative example depicted in FIG. 4 is similar to the micro scanning mirror 100 in FIG. 1A, while the differences therebetween are described below. In the comparative example depicted in FIG. 4, a piezoelectric material layer 130′ of the micro scanning mirror 100′ does not include the first spacing regions SR1 and the second spacing regions SR2; namely, the piezoelectric material layer 130′ is an intact ring-shaped piezoelectric material layer, the surfaces of first rotating shaft elements 140′ and second rotating shaft elements 150′ are an intact rectangular pattern, and the silicon-containing portions of the first rotating shaft elements 140′ and the second rotating shaft elements 150′ and the substrate 110 are integrally formed.

Given the same driving voltage, simulated data of displacement changes or angle changes of the micro scanning mirror 100′ according to the comparative example depicted in FIG. 4 and the micro scanning mirror 100 according to the embodiment depicted in FIG. 1A are exemplified below. The data listed below, however, are not intended to limit the scope of the invention, and people having ordinary skill in the pertinent art may properly modify relevant parameters or settings after referring to the invention without departing from the scope of the invention.

TABLE 1

| | Comparative | Embodiment |
|---|---|---|
| | example depicted | depicted |
| | in FIG. 4 | in FIG. 1A |
| Maximum rotation angle (°) of the lens | 4.9 | 6.1 |
| 120 around the first axial direction D1 | | |
| Maximum rotation angle (°) of the lens | 6 | 6.7 |
| 120 around the second axial direction | | |
| D2 | | |
| Maximum displacement of the lens 120 | 0.8 | 1 |
| in the first axial direction D1 (the values | | |
| are normalized) | | |
| Maximum displacement of the lens 120 | 0.9 | 1 |
| in the second axial direction D2 (the | | |
| values are normalized) | | |
| First resonance frequency (the values | 0.89 | 1 |
| are normalized) | | |

Specifically, according to the data in <Table 1>, given the same driving voltage, the arrangement of the first spacing regions SR1 and the second spacing regions SR2 in the micro scanning mirror 100 provided in the embodiment depicted in FIG. 1A easily leads to the deformation of the substrate 110 and the piezoelectric material layer 130 located on both sides of the first spacing regions SR1 or the second spacing regions SR2 and further enables the lens 120 to reach a relatively large rotation angle when the lens 120 rotates around the first axial direction D1 or around the second axial direction D2. Besides, in general, if the number of connections of elements or the area of the elements at the fixing end increases, rigidity of the elements may be improved. According to the data in <Table 1>, the resonance frequency of the micro scanning mirror 100 in the embodiment depicted in FIG. 1A is greater than the resonance frequency of the micro scanning mirror 100′ in the comparative example in FIG. 4, and here a large resonance frequency of an element indicates great rigidity of the element. That is to say, the micro scanning mirror 100 provided in the embodiment depicted in FIG. 1A may have the improved rigidity through the second rotating shaft elements 150 which connect the fixing end FX of the substrate 110 and the piezoelectric material layer 130 in the two second driving electrode regions DR2.

Accordingly, owing to the arrangement of the first spacing regions SR1 and the second spacing regions SR2 where the piezoelectric material layer 130 is not disposed, the micro scanning mirror 100 may achieve a relatively large rotation angle when the lens 120 rotates around the first axial direction D1 or around the second axial direction D2, so as to reduce the required driving voltage on the condition of the same rotation angle and to mitigate the difficulty of the driving circuit design. Additionally, in the micro scanning mirror 100, the fixing end FX of the substrate 110 and the piezoelectric material layer 130 in the two second driving electrode regions DR2 are connected by the second rotating shaft elements 150, so as to improve the rigidity of the micro scanning mirror 100 and further enhance the reliability of the micro scanning mirror 100.

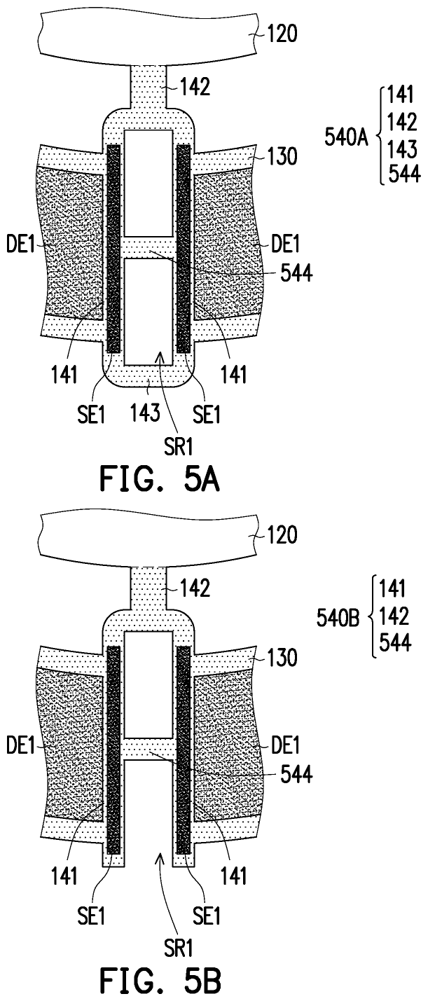

FIG. 5A to FIG. 5C are schematic front views of different first rotating shaft elements according to another embodiment of the invention. With reference to FIG. 5A to FIG. 5C, first rotating shaft elements 540A, 540B, and 540C in FIG. 5A to FIG. 5C are similar to the first rotating shaft elements 140 in FIG. 1A, while the differences therebetween are described below. As shown in FIG. 5A to FIG. 5C, in these embodiments, the first rotating shaft elements 540A, 540B, and 540C all have two first extension portions 141 and the first inner connection portion 142 and may optionally have the outer connection portion 143 or an intermediate connection portion 544. Specifically, in these embodiments, if the first rotating shaft elements 540A and 540B have an intermediate connection portion 544, the intermediate connection portion 544 protrudes from an intermediate portion between the two first extension portions 141 and extends in a direction not parallel to the first axial direction D1, so that the two first extension portions 141 are connected to each other. Here, the direction that is not parallel to the first axial direction D1 may be the circumferential direction of the lens 120 or a direction perpendicular to the first axial direction D1.

More specifically, as shown in FIG. 5A, each first rotating shaft element 540A has both the intermediate connection portion 544 and the outer connection portion 143; thereby, the outline of the first rotating shaft elements 540A may have a pattern shaped as a letter B. On the other hand, as shown in FIG. 5B, each first rotating shaft element 540B does not have the outer connection portion 143, the intermediate connection portion 544 of each first rotating shaft element 540B is farther away from the lens 120 than the first inner connection portion 142 of each first rotating shaft element 540B, and the intermediate connection portion 544 of each first rotating shaft element 140 is closer to the lens 120 than an outer circumference of the piezoelectric material layer 130 located on both two sides of each of the first spacing regions SR1. As such, the outline of the first rotating shaft elements 540B may be shaped as a letter A. In addition, as shown in FIG. 5C, when each first rotating shaft element 540C does not have the intermediate connection portion 544 and the outer connection portion 143, the first rotating shaft elements 540C may have an open-end outline.

Accordingly, when the micro scanning mirror 100 has the first rotating shaft elements 540A, 540B, and 540C, the arrangement of the first spacing regions SR1 and the second spacing regions SR2 where the piezoelectric material layer 130 is not disposed still allows the lens 120 to achieve a relatively large rotation angle when rotating around the first axial direction D1 or the second axial direction D2 and accomplish said effects and advantages, which will not be further explained hereinafter.

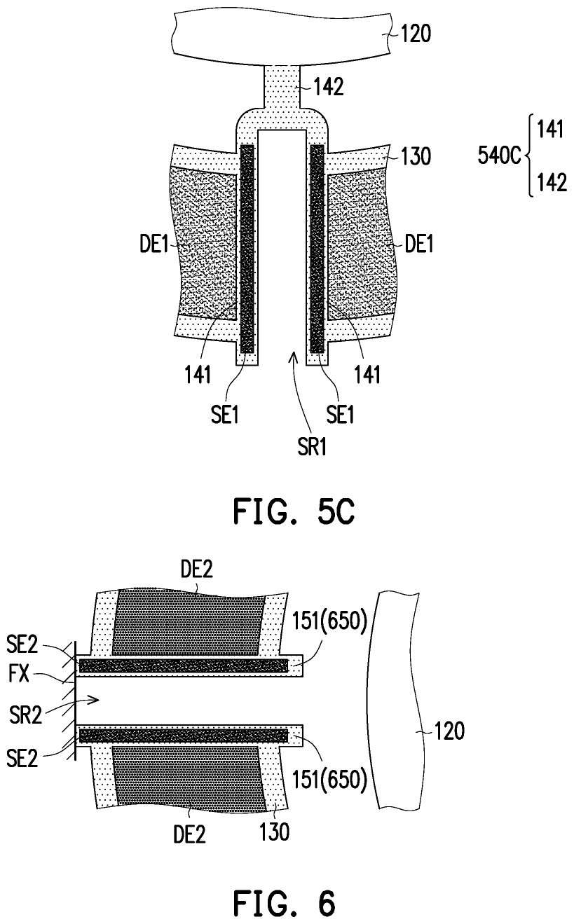

FIG. 6 is a schematic front view of second rotating shaft elements according to another embodiment of the invention. With reference to FIG. 6, second rotating shaft elements 650 in FIG. 6 are similar to the second rotating shaft elements 150 in FIG. 1A, while the differences therebetween are described below. As shown in FIG. 6, in this embodiment, the second rotating shaft elements 650 do not have the second inner connection portion 152 but merely have the two second extension portions 151. Even so, since the micro scanning mirror 100 includes the second rotating shaft elements 650, the micro scanning mirror 100 can still have the improved rigidity through the second rotating shaft elements 650 connecting the fixing end FX of the substrate 110 and the piezoelectric material layer 130 corresponding to two second driving electrodes DE2, the reliability of the micro scanning mirror 100 may be further improved, and said effects and advantages may also be accomplished, which will not be further explained hereinafter. In addition, the second rotating shaft elements 150 in FIG. 1A and FIG. 1D and the second rotating shaft elements 650 in FIG. 6 may also have an intermediate connection portion (not shown) which is similar to the intermediate connection portion 544 depicted in FIG. 5A and FIG. 5B. The intermediate connection portion herein may protrude from an intermediate portion between the two second extension portions 151 and extend in a direction not parallel to the second axial direction D2, so that the two second extension portions 151 are connected to each other, which can further improve the rigidity of the micro scanning mirror 100.

To sum up, one or more embodiments of the invention have at least one of the following advantages or effects. In one or more embodiments of the invention, the micro scanning mirror is provided with the first spacing regions and the second spacing regions where the piezoelectric material layer is not disposed, so that the lens may achieve a relatively large rotation angle when the lens rotates around the first axial direction or the second axial direction, so as to reduce the required driving voltage on the condition of the same rotation angle and to mitigate the difficulty of the driving circuit design. Additionally, in the micro scanning mirror, the fixing end of the substrate and the piezoelectric material layer in the two second driving electrode regions are connected by the second rotating shaft elements, so as to improve the rigidity of the micro scanning mirror and further enhance the reliability of the micro scanning mirror.

The foregoing description of the preferred of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the invention” or the like does not necessarily limit the claim scope to a specific embodiment, and the reference to particularly preferred exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. The abstract of the disclosure is provided to comply with the rules requiring an abstract, which will allow a searcher to quickly ascertain the subject matter of the technical disclosure of any patent issued from this disclosure. It is submitted with the understanding that it will not be used to interpret or limit the scope or meaning of the claims. Any advantages and benefits described may not apply to all embodiments of the invention. It should be appreciated that variations may be made in the embodiments described by persons skilled in the art without departing from the scope of the invention as defined by the following claims. Moreover, no element and component in the disclosure is intended to be dedicated to the public regardless of whether the element or component is explicitly recited in the following claims.

What is claimed is:

1. A micro scanning mirror, comprising a lens, a piezoelectric material layer, two first rotating shaft elements, and a plurality of first driving electrodes, wherein
a first axial direction passes through a center of the lens,
the piezoelectric material layer is arranged along a circumferential direction of the lens, wherein the piezoelectric material layer has a plurality of first driving electrode regions, and two first spacing regions where the piezoelectric material layer is not disposed are respectively formed between two adjacent first driving electrode regions of the plurality of first driving electrode regions,
the two first rotating shaft elements are respectively located on two opposite sides of the lens along the first axial direction, and each of the two first rotating shaft elements is located between one of the two first spacing regions and the corresponding two adjacent first driving electrode regions, wherein each of the two first rotating shaft elements connects the lens and the piezoelectric material layer located in the corresponding two adjacent first driving electrode regions,
the plurality of first driving electrodes are respectively located on corresponding first driving electrode regions of the plurality of first driving electrode regions, and the piezoelectric material layer is respectively driven by corresponding first driving electrodes of the plurality of first driving electrodes, so that the two first rotating shaft elements drive the lens to rotate around the first axial direction after the piezoelectric material layer located on both sides of each of the two first spacing regions is deformed.

2. The micro scanning mirror according to claim 1, wherein the first axial direction passes through the two first spacing regions.

3. The micro scanning mirror according to claim 1, wherein each of the two first rotating shaft elements has two first extension portions and a first inner connection portion, the first inner connection portion is connected to the lens and extends from both ends of the lens toward a radially-outer side of the lens and branches off to form the two first extension portions, and the two first extension portions are connected to the piezoelectric material layer in the two adjacent first driving electrode regions.

4. The micro scanning mirror according to claim 3, wherein the first axial direction passes through the first inner connection portion.

5. The micro scanning mirror according to claim 3, wherein each of the two first rotating shaft elements has an intermediate connection portion protruding from an intermediate portion between the two first extension portions and extending in a direction not parallel to the first axial direction, so that the two first extension portions are connected to each other.

6. The micro scanning mirror according to claim 5, wherein the intermediate connection portion of each of the two first rotating shaft elements is farther from the lens than the first inner connection portion of each of the two first rotating shaft elements, and the intermediate connection portion of each of the two first rotating shaft elements is closer to the lens than an outer circumference of the piezoelectric material layer located on both sides of each of the two first spacing regions.

7. The micro scanning mirror according to claim 3, wherein each of the two first rotating shaft elements further has an outer connection portion, and the outer connection portion protrudes from one end of the two first extension portions and extends along a circumferentially-outer side of the piezoelectric material layer, so that the two first extension portions are connected to each other.

8. The micro scanning mirror according to claim 7, wherein the outer connection portion of each of the two first rotating shaft elements is farther from the lens than an outer circumference of the piezoelectric material layer located on both sides of each of the two first spacing regions.

9. The micro scanning mirror according to claim 1, wherein a direction of a driving voltage applied to the piezoelectric material layer by first driving electrodes of the plurality of first driving electrodes close to one side of each of the two first spacing regions is opposite to a direction of a driving voltage applied to the piezoelectric material layer by first driving electrodes of the plurality of first driving electrodes close to the other side of each of the two first spacing regions.

10. The micro scanning mirror according to claim 1, further comprising:
a plurality of first sensing electrodes, located on the two first rotating shaft elements.

11. The micro scanning mirror according to claim 1, wherein the lens further has a second axial direction, the first axial direction and the second axial direction are orthogonal to each other and intersect at the center of the lens, the piezoelectric material layer further has a plurality of second driving electrode regions, two second spacing regions where the piezoelectric material layer is not disposed are respectively formed between two adjacent second driving electrode regions of the plurality of second driving electrode regions, and the micro scanning mirror further comprises two second rotating shaft elements and a plurality of second driving electrodes, wherein
the two second rotating shaft elements are respectively located on two opposite sides of the lens along the second axial direction, and each of the two second rotating shaft elements is located between one of the two second spacing regions and the corresponding two adjacent second driving electrode regions,
the plurality of second driving electrodes are respectively located on corresponding second driving electrode regions of the plurality of second driving electrode regions, and the piezoelectric material layer is respectively driven by corresponding second driving electrodes of the plurality of second driving electrodes, so that the two second rotating shaft elements drive the lens to rotate around the second axial direction after the piezoelectric material layer located on both sides of each of the two second spacing regions is deformed.

12. The micro scanning mirror according to claim 11, wherein the second axial direction passes through the two second spacing regions.

13. The micro scanning mirror according to claim 11, wherein each of the two second rotating shaft elements is connected to a fixing end of a substrate and located at the piezoelectric material layer in the two second driving electrode regions.

14. The micro scanning mirror according to claim 11, wherein each of the two second rotating shaft elements has two second extension portions and a second inner connection portion, each of the second inner connection portions extends from the piezoelectric material layer located on both sides of each of the two second spacing regions along a circumferentially-inner side of the piezoelectric material layer, so that the piezoelectric material layer located between on both sides of each of the two second spacing regions are connected to each other, each of the second inner connection portions extends from a radially-inner side of the piezoelectric material layer toward a radially-outer side of the piezoelectric material layer to form the two second extension portions, and the two second extension portions are connected to the piezoelectric material layer in the two adjacent second driving electrode regions.

15. The micro scanning mirror according to claim 14, wherein the second inner connection portion of each of the two second rotating shaft elements is closer to the lens than an inner circumference of the piezoelectric material layer located on both sides of each of the two second spacing regions.

16. The micro scanning mirror according to claim 11, wherein a direction of a driving voltage applied to the piezoelectric material layer by second driving electrodes of the plurality of second driving electrodes close to one side of each of the two second spacing regions is opposite to a direction of a driving voltage applied to the piezoelectric material layer by second driving electrodes of the plurality of second driving electrodes close to the other side of each of the two second spacing regions.

17. The micro scanning mirror according to claim 11, further comprising:
a plurality of second sensing electrodes, located on the two second rotating shaft elements.
